(19) United States
(12) Patent Application Publication
(10) Pub. No.: US 2022/0266315 A1
(43) Pub. Date: Aug. 25, 2022

(54) DUAL ELECTRODE ELECTROADHESION AND DUST MITIGATION/CLEANING SYSTEM

(71) Applicant: ONROBOT LOS ANGELES INC., Los Angeles, CA (US)

(72) Inventors: Nicholas Wettels, Los Angeles, CA (US); Asintha Nanayakkara, Woodland Hills, CA (US); Patrick Marshall, Los Angeles, CA (US)

(21) Appl. No.: 17/691,000

(22) Filed: Mar. 9, 2022

Related U.S. Application Data
(63) Continuation of application No. PCT/EP2020/074673, filed on Sep. 3, 2020.
(60) Provisional application No. 62/898,225, filed on Sep. 10, 2019.

(51) Int. Cl. B08B 6/00; B81B 7/02

(52) U.S. Cl. CPC B08B 6/00; B81B 7/02; B81B 2203/04

(57) ABSTRACT

Systems and methods are provided for an electroactuated adhesion system containing a dry adhesive material and at least two patterned electrodes. The two or more patterned electrodes may be capable of promoting or increasing adhesion of the electroactuated adhesion system while simultaneously preventing or mitigating the accumulation of dust, contaminants, or particulates on the surface of the adhesive material.

### CROSS-REFERENCE

This application is a continuation of International Patent Application No. PCT/EP2020/074673, filed Sep. 3, 2020, which claims the benefit of U.S. Provisional Patent App. No. 62/898,225, filed Sep. 10, 2019, which is entirely incorporated herein by reference for all purposes.

### STATEMENT AS TO FEDERALLY SPONSORED RESEARCH

This invention was made with the support of the United States government under Contract number NNX16CP19C by The National Aeronautics and Space Administration.

### BACKGROUND

Artificial fibrillar microstructures have been shown to mimic the dry adhesive capabilities of micro-scale setae on the toes of the gecko lizard. In particular, individual fibrillar microstructures can be configured to conform to an adhering surface to improve real contact area and thereby increase attractive forces (e.g., intermolecular van der Waals forces) between the individual fibers and the contact surface. Dry adhesives, which are not dependent on liquid secretion, can adhere to and release from contact surfaces without leaving residue on the surfaces and with minimal contamination, allowing for repeated uses and longer lifetimes.

Physical characteristics and material properties of fibrillar microstructures can enhance or diminish their adhesive performance. For instance, synthetic fibrillar microstructures may be fabricated or post-treated to comprise tips having specific shapes, such as mushroom-like flaps, that can increase the real contact area between the individual fibers and the contact surface and significantly enhance the dry adhesive performance of these synthetic fibrillar microstructures. In another instance, the synthetic fibrillar microstructures may be fabricated or post-treated to comprise materials having different material properties. In some instances, different material properties, such as material conductivity, may allow for sensing systems to be integrated into the microstructures.

### SUMMARY

Recognized herein is a need to provide dry fibrillar adhesives that resist fouling and can adhere to a variety of surface types other than very smooth surfaces. The incorporation of systems for resisting the adhesion of particulates and creating electrostatic adhesion greatly expands the use-cases for dry fibrillar adhesives by granting the ability to simultaneously cope with adhering to rougher surfaces and cleaning the fibrillar stalks.

In some instances, the accumulation of contaminant particulate matter, such as dust, can diminish the adhesion strength of a system that utilizes an adhesive, such as a dry adhesive, an electrostatic adhesive, or an electroactuated dry adhesive. Recognized herein is a need for systems, methods, and devices for enhanced adhesion capability with reduced dust or particulate contamination. Provided herein are systems, devices, and methods that utilize a multiple-electrode approach for facilitating adhesive strength and particulate cleaning, mitigation, and prevention of accumulation thereof. An adhesive material may interface a target surface (e.g., that is to be adhered to). In some cases, the adhesive material comprises any solid material. In some cases, the adhesive material may demonstrate superior adhesion strength compared to a conventional material. The adhesive may comprise a dry adhesive (e.g., comprising microstructured surface(s)). The adhesive may comprise an electrostatic adhesive. The adhesive may comprise an electroactuated dry adhesive, wherein electrodes are embedded therein or otherwise coupled to a substrate which has a microstructured surface. For example, the adhesive material may be or comprise any microstructured material. In some instances, the adhesive material may comprise two or more electrodes (e.g., embedded therein or otherwise coupled thereto) to form an electroactuated adhesive material. A dry adhesive material may comprise two or more electrodes (e.g., embedded therein or otherwise coupled thereto) to form an electroactuated dry adhesive material. In some instances, electroactuation of a dry adhesive material may increase the adhesion strength of the dry adhesive as compared to the non-electroactuated dry adhesive.

The accumulation of particulate matter, such as dust, may cause a loss of adhesion strength in the adhesive material. The adhesion strength of an adhesive material may be characterized by a separation normal stress strength or a separation shear stress strength when the adhesive material is contacted with the surface of another material. Particulate matter accumulation may be prevented, reduced, mitigated, or cleaned by reducing the adhesion of particles to the dry adhesive surface. In certain aspects, provided are systems, devices, and methods for cleaning or otherwise reducing accumulation of particulate matter from an adhesive surface. In certain aspects, provided are systems, devices, and methods for preventing or otherwise mitigating accumulation of particulate matter on an adhesive surface. The separation of particulate matter may utilize a method such as electrostatic separation to reduce the adhesion strength of the particulate matter to the adhesive surface.

In an aspect, there is provided an electroactuated adhesion system, comprising a substrate comprising a surface, wherein the surface comprises a plurality of microstructures where the plurality of microstructures are configured to interface a target surface. The electroactuated adhesion system further comprises two or more patterned electrodes embedded therein or coupled to the substrate where each patterned electrode (i) comprises a conductive material of a respective predetermined thickness, and (ii) is patterned in the substrate to have a respective predetermined minimum separation gap between substantially parallel segments of the each patterned electrode. The electroactuated adhesion system also comprises one or more voltage-generating systems in electrical connectivity with the two or more patterned electrodes where the one or more voltage-generating systems are configured to activate the two or more patterned electrodes, individually or simultaneously.

In some embodiments, one or both of the predetermined minimum separation gap and the predetermined thickness is determined based at least in part on the type of target surface.

In some embodiments, the substrate comprises an elastomer.

In some embodiments, the conductive material comprises one or more materials selected from the group consisting of: copper, silver, graphite, brass, titanium, platinum, palladium, and mixed metal oxides. In some embodiments, the electrode comprises one or more materials selected from the group consisting of: copper, silver, graphite, brass, titanium, platinum, palladium, and mixed metal oxides.

In some embodiments, the predetermined thickness of the conductive material is at least about 50 microns. In some embodiments, the predetermined thickness of the conductive material is no more than about 500 microns. In some embodiments, the predetermined separation gap of a given patterned electrode is at least about 100 microns. In some embodiments, the predetermined separation gap of the given patterned electrode is no more than about 1 millimeter.

In some embodiments, a first predetermined separation gap of a first patterned electrode of the two or more patterned electrodes differs from a second predetermined separation gap of a second patterned electrode of the two or more patterned electrodes. In some embodiments, a first patterned electrode of the two or more patterned electrodes comprises a larger thickness of the conductive material and a smaller separation gap, and a second patterned electrode of the two or more patterned electrodes comprises a smaller thickness of the conductive material and a larger separation gap.

In some embodiments, the first patterned electrode is configured to facilitate adhesion to the target surface, and the one or more voltage-generating systems are configured to activate the first patterned electrode to adhere to the target surface. In some embodiments, the second patterned electrode is configured to facilitate cleaning of a surface of the dry adhesive material, the one or more voltage-generating systems are configured to activate the first patterned electrode to (i) clean the surface or (ii) prevent particulate accumulation on the surface.

In some embodiments, the electroactuated adhesion system further comprises a microprocessor system. In some embodiments, the microprocessor system is configured to control the one or more voltage-generating systems. In some embodiments, the microprocessor system is configured to (i) receive a capacitance measurement from the two or more patterned electrodes, and (ii) determine one or more contact properties with the target surface. In some embodiments, the microprocessor system is configured to transmit a voltage input instruction to the one or more voltage-generating systems. In some embodiments, the voltage input instruction is based at least in part on a type of the target surface.

In some embodiments, the substrate is configured to adhere to a plurality of adjacent materials comprising the target surface.

In some embodiments, the two or more patterned electrodes are embedded in a single layer of the substrate. In some embodiments, the two or more patterned electrodes are embedded in a plurality of layers of the substrate.

In another aspect, provided is a method comprising: (a) providing any of the electroactuated adhesion systems described herein, including the above embodiments; and (b) causing the one or more voltage-generating to activate an electrode of the two or more patterned electrodes.

In some embodiments, the method further comprises causing the one or more voltage-generating systems to activate an additional electrode of the two or more patterned electrodes, individually or simultaneously with the electrode.

Another aspect of the present disclosure provides a non-transitory computer readable medium comprising machine executable code that, upon execution by one or more computer processors, implements any of the methods above or elsewhere herein.

Another aspect of the present disclosure provides a system comprising one or more computer processors and computer memory coupled thereto. The computer memory comprises machine executable code that, upon execution by the one or more computer processors, implements any of the methods above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings (also “Figure” and “FIG.” herein), of which:

FIG. 1A depicts a schematic view of a microstructured dry adhesive surface under no load.

FIG. 1B depicts a schematic view of a microstructured dry adhesive surface under a shear load.

FIG. 1C depicts a schematic view of another example of a microstructured dry adhesive surface.

FIG. 2 shows a schematic example of a microstructured dry adhesive material with associated electronic components.

FIG. 3 illustrates a conceptual schematic of a computational system as provided in the present disclosure.

FIG. 4 depicts a schematic of an electroactuated adhesion device comprising two electrodes with varying separation gaps.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The present disclosure provides various methods and systems for simultaneously optimizing electroactuated adhesion of adhesive materials to various surfaces and preventing and/or removing the accumulation of particulate matter or other contaminants on electroactuated adhesive materials. The present disclosure provides various methods and systems for increasing adhesive strength of adhesives and mitigating particulate contamination.

An adhesive material of the present disclosure may comprise a substrate with any type of surface, such as a microstructured gripping surface, substantially planar gripping surface, patterned gripping surface, unpatterned gripping surface, textured gripping surface, untextured gripping surface, etc.

In some instances, the adhesive material may be an electrostatic adhesive material. Electrostatic adhesives may comprise one or more conductive electrodes embedded inside a dielectric material adjacent to a substrate or otherwise coupled adjacent to the substrate, the substrate configured to interface a target surface (e.g., to be gripped). Upon application of a voltage or current across the electrodes, the electric field generated may create an adhesive force on or through the substrate. For example, for conductive substrates, electrons will migrate towards the positive electrodes, and generate a set of capacitors from the electrodes and the substrates. For non-conductive substrates, the molecules of the substrate may be polarized.

In some instances, in addition or alternatively, the adhesive material may be a dry adhesive material. Dry adhesive materials may be microstructured, and/or comprise microstructures, using engineered materials, such as elastomers, to increase their adhesion strength.

In some instances, dry adhesives may be combined with embedded multi-electrode systems to enhance their adhesion strength. Dry adhesive materials that are associated with multiple electrodes (e.g., having embedded therein, having coupled thereto, in electrical communication with, etc.) may generally be referred to herein as electroactuated dry adhesives. The combination of van der Waals and electrostatic interactions may create an adhesion strength that is greater than the sum of either interaction alone.

In certain operating environments, e.g., a manufacturing facility, incidental contact of the adhesive materials with particulate matter of varying sizes may be unavoidable. In some instances, particulate matter may be located on surfaces or may be airborne as a suspension or aerosol when it contacts such adhesive materials. At the length scales of interest to dry adhesion, the accumulation of particulate matter, such as dust particles, may be a major concern.

The present disclosure describes various methods and system for actively utilizing a multi-electrode dry adhesive material to adhere to a surface and prevent or minimize particulate matter accumulation on the dry adhesive material. The present disclosure may also describe methods for removing incidental or unavoidable particulate accumulation on the dry adhesive material. In certain aspects, provided are systems, devices, and methods for cleaning or otherwise reducing accumulation of particulate matter from an adhesive surface. In certain aspects, provided are systems, devices, and methods for preventing or otherwise mitigating accumulation of particulate matter on an adhesive surface. In some instances, a dry adhesive material may have an associated system of two or more electrodes that facilitate particulate matter separation and prevention by electrostatic repulsion. Methods of preventing particulate accumulation may include non-contact methods. The described methods and systems may be utilized individually or in combination to maintain the adhesion properties of dry adhesive materials.

Various terms used throughout the present description may be read and understood as follows, unless the context indicates otherwise: “or” as used throughout is inclusive, as though written “and/or”; singular articles and pronouns as used throughout include their plural forms, and vice versa; similarly, gendered pronouns include their counterpart pronouns so that pronouns should not be understood as limiting anything described herein to use, implementation, performance, etc. by a single gender; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description.

The term “elastomer” in the descriptions herein, refers to a material that changes properties in response to an applied force. Elastomers, in various formulations, respond to normal forces, compression, torque, or sheer stresses or forces. Some elastomers are also referred to as “rubber,” “polymer,” or “silicone.” Typically, but not always, an elastomer responds to an applied force with a physical deformation. Additionally, elastomers can be designed to change various properties such as impedance in response to applied force, stress, or torque. Elastomers can be configured to change properties when stressed in one dimension, or in multiple dimensions.

Elastomers can be formulated and produced with various properties that may be desirable for a given application, for example desired flexibility, stiffness (i.e. spring constant or dimensional change in response to pressure), conformability (i.e. ability to follow a curved or complex contour), thickness, color, or electrical or heat conductivity. Another property of an elastomer is “durometer,” which is its hardness or resistance to permanent deformation. An adhesive material of the present disclosure can comprise elastomeric material. Dry adhesive materials of the present disclosure can comprise dielectric elastomeric material, for example.

Provided herein are electroactuated dry adhesives. Dry adhesive may comprise one or more microstructured surfaces. Microstructures having different physical characteristics, such as in shape, size, and/or volume, can comprise different adhesive properties. In some aspects, physical characteristics, such as a shape, size, or volume, of microstructures in a dry adhesive may affect the degree of van der Waals interactions between the microstructures and a contact surface to enhance or diminish overall adhesive performance. In some instances, the microstructures may be post-treated to change one or more physical characteristics to improve adhesive performance.

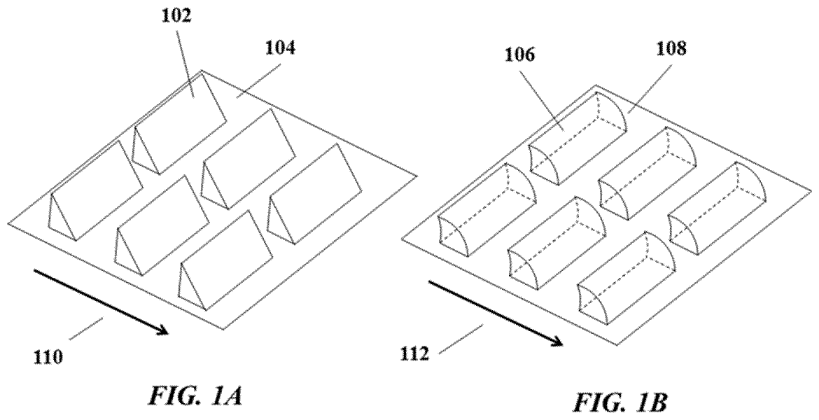

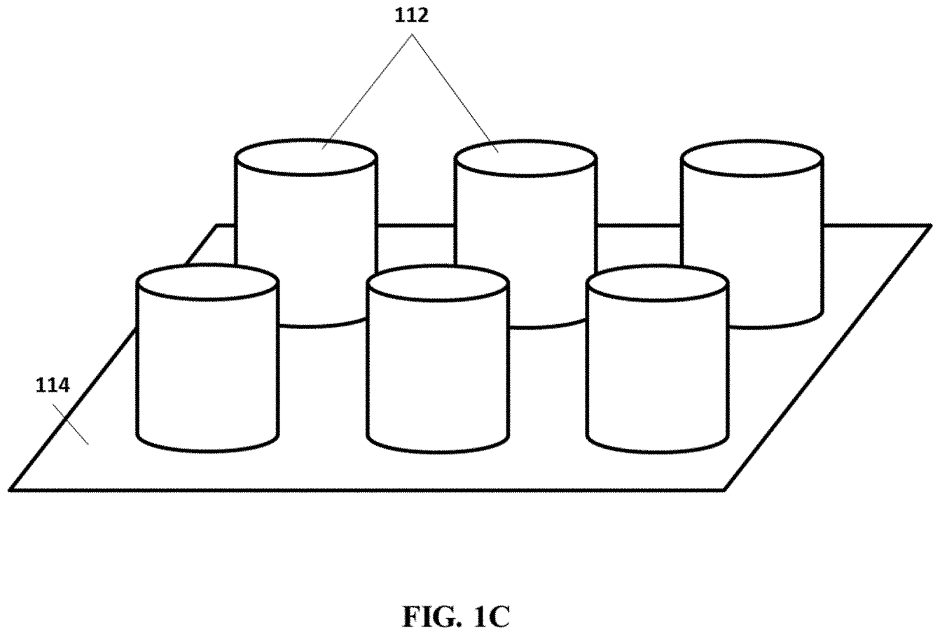

FIG. 1A illustrates a perspective view of exemplary microstructures on a surface of a gripping pad in an unloaded state. FIG. 1A is not drawn to scale. A plurality of microstructures 102 may populate a surface 104 of a gripping pad or any other surface intended for adhesion. The surface 104 can represent a sample portion of a larger surface intended for adhesion. Surfaces comprising microstructures, such as the surface 104, may also be referred to as backing layers. A microstructure stalk may comprise two ends, a first end rooted in the backing layer and a second end, such as a tip of the stalk, extending longitudinally away from the backing layer. The tip of a microstructure stalk may be pointed. Alternatively the tip of a microstructure stalk may be flat, rounded, or comprise a more complex pattern. Each of the microstructures 102 may comprise substantially uniform geometric structures. For example, FIG. 1A shows an array of uniform wedge-like microstructures wherein the cross-sectional front view of each microstructure is triangular with a base rooted on the surface 104 and a tip extending longitudinally away from the surface 104. Alternatively, the microstructures 102 may comprise conical, cylindrical, cubical, trapezoidal, or other more complex geometric structures with similar or different cross-sectional shapes.

The microstructures 102 can have micro-scale dimensions. For instance, a microstructure can have a maximum dimension of less than about 300, 250, 200, 150, 140, 130, 120, 110, 100, 90, 80, 70, 60, 50, 45, 40, 35, 30, 25, 20, 15, 10, 9, 8, 7, 6, or less than about 5 μm. A maximum dimension of the microstructure may be a dimension of the microstructure (e.g., length, width, height, altitude, diameter, etc.) that is greater than the other dimensions of the microstructure. In one example, the wedge-like microstructure can have a dimension of about 60 μm in height, 20 μm in width, and 200 μm in length. In some instances, each of the microstructures 102 may be laid out on the surface 104 in an evenly-spaced array or a grid-like pattern. For example, an edge of the base of each microstructure 102 may be separated from the closest edge of the base of a neighboring microstructure by a distance of about 20-40 μm. In other instances, each of the microstructures 102 may be laid out in an arbitrary pattern with non-uniform gaps between each microstructure.

A dry adhesive may be customized to conform with objects of varying shapes, sizes, or surface characteristics. In some examples, an object may comprise a flat surface or a curved, warped, or otherwise irregular surface. A device comprising one or more dry adhesive pads may be customized to conform to a shape of an object surfaces. In some instances, a device comprising multiple dry adhesive pads may angle or articulate each pad separately to optimize the adhesion of the pads to the object surface. In other instances, a single dry adhesive pad may conform to the surface of an object to maximize the adhesion of the pad to the object.

The backing layer can have any thickness. For instance, the backing layer can have a maximum thickness of at most about 5 millimeters (mm), 4.5 mm, 4 mm, 3.5 mm, 3 mm, 2.5 mm, 2 mm, 1.5 mm, 1 mm, 0.5 mm, 0.4 mm, 0.3 mm, 0.2 mm, 0.1 mm or less. Alternatively or in addition, the backing layer can have a maximum thickness of at least about 0.1 mm, 0.2 mm, 0.3 mm, 0.4 mm, 0.5 mm, 1 mm, 1.5 mm, 2 mm, 2.5 mm, 3 mm, 3.5 mm, 4 mm, 4.5 mm, 5 mm or more. In some instances, a dry adhesive material may be bonded to or layered with one or more backing layers.

Directional control, wherein the gripping surface comprising the microstructures 102 is configured to adhere to a contact surface when a shear load is applied in a preferred direction 110 and detach when the shear load is relaxed, can be achieved by orienting each microstructure 102 in substantially the same direction on the surface 104. The tip, or a characteristic axis, of each microstructure can be configured to tilt away from the preferred direction 110 of shear load. The characteristic axis can be a longitudinal axis. In the unloaded state, as in FIG. 1A, the tips of the wedge-like microstructure 102 allow only for minimal contact area between the microstructures and a contact surface, which allows for relatively low van der Waals interactions and therefore low adhesive performance. When a shear load is applied to the microstructures 102 in the preferred direction 110, the microstructures 102 can conform, or bend, against the contact surface, as in FIG. 1B (contact surface not shown), in a direction opposite the preferred direction 110 such that the contact area between the microstructures and the contact surface significantly increases, which allows for relatively high van der Waals interactions and therefore higher adhesive performance. When the shear load is relaxed, the microstructures 102 can revert to the initial unloaded state, as in FIG. 1A. The microstructures 102 may comprise a compliant material (e.g., elastomers) that can withstand repeated structural conformations between the unloaded state and the loaded state. The materials comprising the microstructures will be discussed further below.

FIG. 1B illustrates a perspective view of example microstructures on a surface of a gripping pad in a loaded state. FIG. 1B is not drawn to scale. A plurality of microstructures 106 may populate a surface 108 of a gripping pad or any other surface intended for adhesion. In the loaded state, as described above, a shear load is applied in a preferred direction 112 which bends the microstructures 106 against a contact surface (not shown in FIG. 1B) in a direction opposite the preferred direction 112, increasing the real contact area between the microstructures 106 and the contact surface. A wedge-like structure, with an extended length along an axis, may provide increased contact area along the extended length. In some instances, the surfaces 104 and 108 can be the same surface, the preferred directions 110 and 112 can be the same direction, and the microstructures 102 and 106 may represent the same microstructures in an unloaded state and a loaded state, respectively.

FIG. 1C depicts a schematic view of another example of a microstructured dry adhesive surface. An array of uniform cylindrical pillar-like microstructures 112 may be rooted on the surface 114, with the tip extending longitudinally away from the surface 114. For example, a front cross-sectional shape may be substantially rectangular and/or a top cross-sectional shape may be substantially circular. The microstructures may have a uniform cross-sectional diameter from the base to the tip. An example dimension is about 50 μm in height and about 20 μm in diameter, with about 20 μm spacing distance between neighboring microstructures. It will be appreciated that the microstructures may have any form factor with micro-scale dimensions. A discussion of dry adhesive microstructures, and treatment thereof, are provided in International Patent Pub. No. WO2018/170471, which is entirely incorporated herein by reference for all purposes.

In some instances, the above-described microstructured dry adhesive materials may be applied as a layer to a surface or element of a mechanical or robotic system. Microstructured dry adhesive materials may be utilized for various purposes including, but not limited to, gripping and sensing. In some instances, a dry adhesive material comprising two or more embedded electrodes may be utilized for multiple purposes, such as adhesion and cleaning, adhesion and sensing, cleaning and sensing, or adhesion, cleaning, and sensing. A sensing dry adhesive material may utilize an impedance measurement in one or more electrodes to sense contact with a target material and/or determine a material property or characteristic when the material is contacted. In some instances, a material property or characteristic may be inferred by, and/or calculated from, a change in impedance when contact is made with the material.

A dry adhesive pad may be electroactuated. An electroactuated pad may be activated via applying a current or voltage to one or more patterned electrodes embedded in or otherwise coupled to the dry adhesive material. For example, such current or voltage may be applied prior to, during, or subsequent to making contact with an object's surface. In some instances, activation of an electroactuated dry adhesive material may comprise making the surface microstructures become co-planar at the microscale level. The electroactuated pad can be used to actuate adhesion. In some instances, when actuated, the electrostatic adhesion may facilitate conformance of the dry adhesives to the target surface (to the target surfaces shape), thereby strengthening adhesive forces for both electrostatic adhesion (minimizing distance to target surface) and dry adhesion (increasing contact surface area between the microstructure stalks and the target surface).

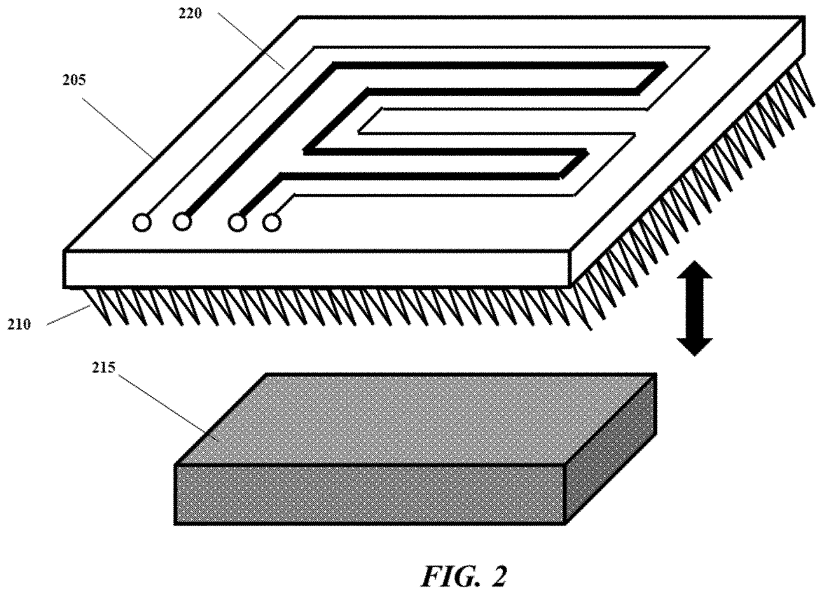

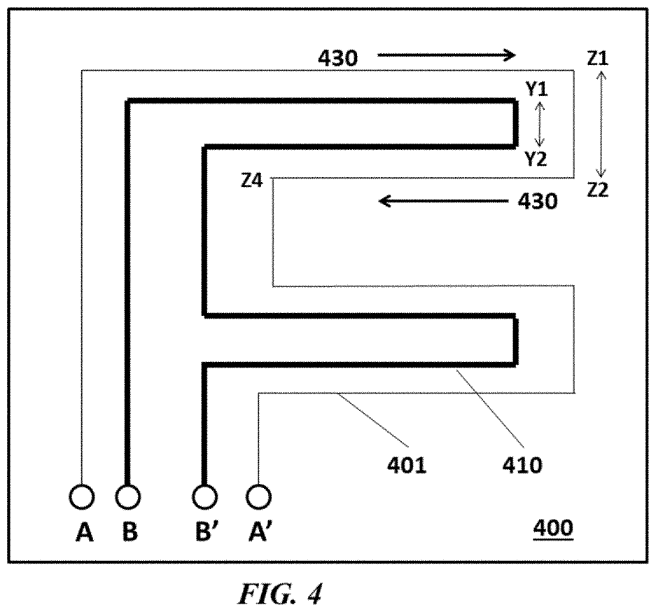

FIG. 2 illustrates an example of an electroactuated dry adhesive pad substrate 205 comprising a surface having microstructures 210 and having electronic components 220 patterned on, embedded in, or otherwise coupled thereto the pad substrate 205. The microstructured surface may be configured to face a contact surface 215 of a target object to be gripped by the pad. The electronic components 220 are described in further detail elsewhere herein, such as with respect to FIG. 4.

The material of the dry adhesive pad substrate 205, such as the material of the backing layer and/or the material of the microstructure stalks, may be chosen to optimize one or more material or chemical properties, including surface roughness, elastic modulus, work of adhesion, work of separation, elastic strength, compressive strength, shear strength, stiffness, toughness, homogeneity, isotropy, elasticity, plasticity, resilience, damping, thermal conductivity, thermal expansion, heat capacity, density, electrical conductivity, dielectric strength, electrical resistivity, electrical conductivity, UV resistance, oxidative resistance, and chemical inertness. In some instances, the material may comprise a polymer or a blend of polymers. In some instances, the material may be elastomeric. In some instances, the material may be dielectric.

In some instances, the dry adhesive pad may be designed to have a particular surface roughness. Without wishing to be bound by theory, surface roughness may be defined as the average deviation in the form of a surface relative to its ideal form. In some examples, the surface roughness may represent the average height of surface structures above an average surface level. The surface roughness may be considered an intrinsic material property (i.e. artifactual of the material synthesis process) in comparison to the above-described engineering of microstructures in the dry adhesive material. Surface roughness may be determined by various surface metrology methods, including, but not limited to, confocal microscopy, interferometry, holography, scanning electron microscopy (SEM), and atomic force microscopy (AFM). A material for a dry adhesive may be chosen based upon the value of its surface roughness. A dry adhesive material may have a surface roughness of about 0.5 nanometers (nm), 1 nm, 2 nm, 3 nm, 4 nm, 5 nm, 6 nm, 7 nm, 8 nm, 9 nm, 10 nm, 15 nm, 20 nm, 25 nm, 50 nm or about 100 nm. A dry adhesive material may have a surface roughness of at least about 0.5 nanometers (nm), 1 nm, 2 nm, 3 nm, 4 nm, 5 nm, 6 nm, 7 nm, 8 nm, 9 nm, 10 nm, 15 nm, 20 nm, 25 nm, 50 nm or at least about 100 nm or more. A dry adhesive material may have a surface roughness of no more than about 100 nm, 50 nm, 25 nm, 20 nm, 15 nm, 10 nm, 9 nm, 8 nm, 7 nm, 6 nm, 5 nm, 4 nm, 3 nm, 2 nm, 1 nm, or no more than about 0.5 nm or less. A dry adhesive material may be chosen with a surface roughness in a range from about 0.5 nm to about 2 nm, about 0.5 nm to about 5 nm, about 0.5 nm to about 10 nm, about 0.5 nm to about 50 nm, about 0.5 nm to about 100 nm, about 2 nm to about 5 nm, about 2 nm to about 10 nm, about 2 nm to about 50 nm, about 2 nm to about 100 nm, about 5 nm to about 10 nm, about 5 nm to about 50 nm, about 5 nm to about 100 nm, about 10 nm to about 50 nm, about 10 nm to about 100 nm, or about 50 nm to about 100 nm.

In some instances, the dry adhesive pad may be designed to have a particular elastic modulus. In some instances, the elastic modulus may specifically refer to the Young's modulus of a particular material. In other instances, the elastic modulus may refer to the shear modulus or bulk modulus. Without wishing to be bound by theory, the elastic modulus may be defined as the amount of deformation in a material due to an applied force or stress. In some instances, the elastic modulus may be defined as the ratio of stress to strain along an axis in a material experiencing deformation along the axis. An elastic modulus may be measured by any suitable instrument for the measurement of such mechanical properties. A material for a dry adhesive may be chosen based upon the value of its elastic modulus. A dry adhesive material may have an elastic modulus of about 0.5 megaPascals (MPa), 0.6 MPa, 0.7 MPa, 0.8 MPa, 0.9 MPa, 1.0 MPa, 1.1 MPa, 1.2 MPa, 1.3 MPa, 1.4 MPa, 1.5 MPa, 1.6 MPa, 1.7 MPa, 1.8 MPa, 1.9 MPa, 2.0 MPa, 2.1 MPa, 2.2 MPa, 2.3 MPa, 2.4 MPa, 2.5 MPa, 2.6 MPa, 2.7 MPa, 2.8 MPa, 2.9 MPa, 3.0 MPa, 5 MPa, 10 MPa, 50 MPa, or about 100 MPa. A dry adhesive material may have an elastic modulus of at least about 0.5 MPa, 0.6 MPa, 0.7 MPa, 0.8 MPa, 0.9 MPa, 1.0 MPa, 1.1 MPa, 1.2 MPa, 1.3 MPa, 1.4 MPa, 1.5 MPa, 1.6 MPa, 1.7 MPa, 1.8 MPa, 1.9 MPa, 2.0 MPa, 2.1 MPa, 2.2 MPa, 2.3 MPa, 2.4 MPa, 2.5 MPa, 2.6 MPa, 2.7 MPa, 2.8 MPa, 2.9 MPa, 3.0 MPa, 5 MPa, 10 MPa, 50 MPa, or at least about 100 MPa or more. A dry adhesive material may have an elastic modulus of no more than about 100 MPa, 50 MPa, 10 MPa, 5 MPa, 3.0 MPa, 2.9 MPa, 2.8 MPa, 2.7 MPa, 2.6 MPa, 2.5 MPa, 2.4 MPa, 2.3 MPa, 2.2 MPa, 2.1 MPa, 2.0 MPa, 1.9 MPa, 1.8 MPa, 1.7 MPa, 1.6 MPa, 1.5 MPa, 1.4 MPa, 1.3 MPa, 1.2 MPa, 1.1 MPa, 1.0 MPa, 0.9 MPa, 0.8 MPa, 0.7 MPa, 0.6 MPa, or no more than about 0.5 MPa or less. A dry adhesive material may be chosen with an elastic modulus in a range from about 0.5 MPa to about 1.0 MPa, about 0.5 MPa to about 1.5 MPa, about 0.5 MPa to about 2.0 MPa, about 0.5 MPa to about 2.5 MPa, about 0.5 MPa to about 3.0 MPa, about 0.5 MPa to about 10 MPa, about 1.0 MPa to about 1.5 MPa, about 1.0 MPa to about 2.0 MPa, about 1.0 MPa to about 2.5 MPa, about 1.0 MPa to about 3.0 MPa, about 1.0 MPa to about 10 MPa, about 1.5 MPa to about 2.0 MPa, about 1.5 MPa to about 2.5 MPa, about 1.5 MPa to about 3.0 MPa, about 1.5 MPa to about 10 MPa, about 2.0 MPa to about 2.5 MPa, about 2.0 MPa to about 3.0 MPa, about 2.0 MPa to about 10 MPa, about 2.5 MPa to about 3.0 MPa, about 2.5 MPa to about 10 MPa, or about 3.0 MPa to about 10 MPa.

In some instances, a dry adhesive may be characterized by a work of adhesion. Without wishing to be bound by theory, a work of adhesion may be defined as the free energy change when an interface is broken between two materials. A dry adhesive material may have a work of adhesion of about 0.5 milliJoules per square meter (mJ/m²), 1 mJ/m², 2 mJ/m², 3 mJ/m², 4 mJ/m², 5 mJ/m², 6 mJ/m², 7 mJ/m², 8 mJ/m², 9 mJ/m², 10 mJ/m², 11 mJ/m², 12 mJ/m², 13 mJ/m², 14 mJ/m², 15 mJ/m², 16 mJ/m², 17 mJ/m², 18 mJ/m², 19 mJ/m², 20 mJ/m², 30 mJ/m², 40 mJ/m², or about 50 mJ/m². A dry adhesive material may have a work of adhesion of at least about 0.5 mJ/m², 1 mJ/m², 2 mJ/m², 3 mJ/m², 4 mJ/m², 5 mJ/m², 6 mJ/m², 7 mJ/m², 8 mJ/m², 9 mJ/m², 10 mJ/m², 11 mJ/m², 12 mJ/m², 13 mJ/m², 14 mJ/m², 15 mJ/m², 16 mJ/m², 17 mJ/m², 18 mJ/m², 19 mJ/m², 20 mJ/m², 30 mJ/m², 40 mJ/m², or at least about 50 mJ/m² or more. A dry adhesive material may have a work of adhesion of no more than about 50 mJ/m², 40 mJ/m², 30 mJ/m², 20 mJ/m², 19 mJ/m², 18 mJ/m², 17 mJ/m², 16 mJ/m², 15 mJ/m², 14 mJ/m², 13 mJ/m², 12 mJ/m², 11 mJ/m², 10 mJ/m², 9 mJ/m², 8 mJ/m², 7 mJ/m², 6 mJ/m², 5 mJ/m², 4 mJ/m², 3 mJ/m², 2 mJ/m², 1 mJ/m², or no more than about 0.5 mJ/m² or less.

In some instances, a dry adhesive material may be characterized by a work of separation. Without wishing to be bound by theory, a work of separation may be defined as the reversible work necessary to break an interface between two materials. A dry adhesive material may have a work of separation of about 50 mJ/m², 75 mJ/m², 100 mJ/m², 110 mJ/m², 120 mJ/m², 130 mJ/m², 140 mJ/m², 150 mJ/m², 160 mJ/m², 170 mJ/m², 180 mJ/m², 190 mJ/m², 200 mJ/m², 250 mJ/m², 300 mJ/m², or about 400 mJ/m². A dry adhesive material may have a work of separation of at least about 50 mJ/m², 75 mJ/m², 100 mJ/m², 110 mJ/m², 120 mJ/m², 130 mJ/m², 140 mJ/m², 150 mJ/m², 160 mJ/m², 170 mJ/m², 180 mJ/m², 190 mJ/m², 200 mJ/m², 250 mJ/m², 300 mJ/m², or at least about 400 mJ/m² or more. A dry adhesive material may have a work of separation of no more than about 400 mJ/m², 300 mJ/m², 250 mJ/m², 200 mJ/m², 190 mJ/m², 180 mJ/m², 170 mJ/m², 160 mJ/m², 150 mJ/m², 140 mJ/m², 130 mJ/m², 120 mJ/m², 110 mJ/m², 100 mJ/m², 75 mJ/m², or no more than about 50 mJ/m² or less.

The separation shear stress strength of a dry adhesive material may be correlated to one or more physical properties of the material. In some instances, the separation shear stress strength of a microstructured dry adhesive with a smooth surface, such as glass, may be predicted by a power law relationship. In a particular instance, the separation shear stress strength of a microstructured dry adhesive with a smooth glass surface may correlate with the square root of the product of the material's work of separation and elastic modulus. In some instances, the separation shear strength of a dry adhesive material may agree with a predictive model, for example Kendall's peeling model.

An electrode of the present disclosure can be any conductive pathway, such as from a first reference point to a second reference point. For example, an electrode can be a conductive wire or sheet. An electrode can be flexible. An electrode can be metallic or non-metallic. For example, an electrode can be formed of a polymeric material with higher electrical conductivity than the adjacent material or environment in which the electrode lies or contacts. An electrode can be formed of a carbon-containing material, such as carbon powder or carbon nanostructures. In some instances, an electrode can be housed in, or adjacent to, an insulating material. The electrode may comprise any conductive material (or relatively conductive than a surrounding material). For example, the electrode may comprise copper, graphite, titanium, brass, silver, platinum, palladium, mixed metal oxide (an inert metal or carbon core coated by an oxide), or any combination thereof.

An electrode can be embedded or integrated into the dry adhesive pad 205. For example, the electrode can be embedded or integrated in relatively flexible or rigid material. In some instances, the pad can comprise different component volumes with different conductivities to achieve this. Component volumes with high conductivity can act as conductive pathways and/or conductive threads, which can be analogous to electrodes and/or wiring thereof. For example, an elastomeric skin can comprise a high conductivity polymeric material for some component volumes and a low conductivity material for some component volumes. In some instances, a high conductivity polymeric material (e.g., elastomer) can have a resistivity from about 0.0001 Ohm-cm and 100 Ohm-cm, or about 0.001 Ohm-cm and 10 Ohm-cm. A low-conductivity polymeric material can have a resistivity from about 10 Ohm-cm and 100 kOhm-cm, or about 100 Ohm-cm and 10 kOhm-cm. Advantageously, via the conductive pathways (or tunnels) and/or conductive threads formed through the pad material, electrical contact points which are vulnerable to damage can be shielded from external stress. Examples of forming conductive pathways and different component volumes are provided in U.S. Pat. No. 9,579,801, which is entirely incorporated herein by reference. Such conductive pathways and/or conductive threads can be integrated into the pad material via methods such as molding and/or three dimensional (3D) printing. In some instances, different layers of the pad material may have different conductivities. A layer may have different conductivities (e.g., within different regions). A layer may have one or more embedded electrodes. A layer may not have any electrodes.

Alternatively, an electrode (e.g., wire) can be otherwise coupled to the dry adhesive pad, such as by any one or more fastening mechanisms described herein. Examples of fastening mechanisms may include, but are not limited to, complementary threading, form-fitting pairs, hooks and loops, latches, threads, screws, staples, clips, clamps, prongs, rings, brads, rubber bands, rivets, grommets, pins, ties, snaps, velcro, adhesives (e.g., glue), tapes, vacuum, seals, magnets, magnetic seals, a combination thereof, or any other types of fastening mechanisms.

Electrodes may be utilized to generate electric fields that alter the adhesion properties or other properties of the surface or volume of the dry adhesive pad. Electrodes may be utilized to prevent, reduce, or mitigate the accumulation of particulate matter or other contaminants or to separate particulate matter or other contaminants from the surface of the dry adhesive. Electrodes may be utilized as a component of a sensing system.

In some instances, electrodes electrically coupled to a dry adhesive material may be activated (e.g., by applying a current or voltage) to achieve higher adhesive strength. Electrostatic dry adhesives that achieve higher adhesive strength are described in U.S. Patent Publication No. 2014/0272272, which is entirely incorporated herein by reference for all purposes. In some instances, electrodes electrically coupled to a dry adhesive material may be activated to achieve electrostatic cleaning, as described elsewhere herein. In some instances, electrodes may be activated to achieve, simultaneously or substantially simultaneously, higher adhesive strength of a dry adhesive material and cleaning (e.g., prevention and removal of contaminant particulate matter) of the dry adhesive surface. In some instances, the electrodes may be used sequentially to first clean the adhesive surface (e.g., by activating certain electrodes), and next increase adhesive strength with respect to a target surface during adhesion of the target surface (e.g., by activating certain electrodes). In other examples, the electrodes may be used sequentially to first increase adhesive strength with respect to a target surface during adhesion of the target surface (e.g., by activating certain electrodes), and then clean the adhesive surface (e.g., by activating certain electrodes).

In some instances, a dry adhesive material may comprise multiple patterned electrodes to control one or more properties, such as adhesion strength or cleanability of an adhesive surface. In some instances, the pattern of the multiple patterned electrodes may be optimized for multiple properties, such as adhesion strength and cleanability of an adhesive surface. In some instances, a width of a patterned electrode may be optimized for multiple properties, such as adhesion strength and cleanability of an adhesive surface. For example, an electrode may be designed to have relatively smaller width to achieve optimal cleaning performance, and relatively larger width to achieve optimal adhesive performance. In some instances, the width of the electrode may be optimized to achieve optimal performance of both cleaning and adhesive functions. In some instances, the width of the electrode may be optimized based on a target material that the electroactuated dry adhesive is designed to grip. In another example, an electrode pattern may be designed to have relatively wider gaps in the pattern to achieve optimal optical cleaning performance, and relatively narrower gaps in the pattern to achieve optimal adhesive performance. In some instances, the gaps(s) in the pattern may be optimized to achieve optimal performance of both cleaning and adhesive functions. As used herein, a ‘width’ of an electrode or a ‘thickness’ of an electrode, used interchangeably herein, may refer to the dimension substantially parallel to a plane of the substrate surface in which the electrode(s) are patterned therein or thereon, distinguished from a ‘depth’ dimension which is substantially normal to the above-described plane (e.g., such that the depth is measured along an axis going into the substrate, e.g., a z-axis), and distinguished from a ‘length’ dimension which typically corresponds to a measurement along a direction of current flow.

A dry adhesive material comprising two or more patterned electrodes may be customized for its intended application. In some instances, the electrode material, electrode patterning, or electrode operation (e.g., including voltage input, duration of operation, order of operation, etc.) may be customized for a specific or intended application (e.g. sorting of materials). In some instances, a dry adhesive material comprising two or more patterned electrodes may be designed for broad uses or applications (e.g., sorting many types of materials). In some instances, a dry adhesive material comprising two or more patterned electrodes may be designed for stacking uses or applications (e.g., to gripping two or more stacked materials simultaneously or substantially simultaneously through one material). Various aspects of the dry adhesive material may be varied to create customized materials for specific applications. In some instances, the thickness of a dry adhesive may be varied. In other instances, the two or more patterned electrodes may be located at an optimal depth within the dry adhesive material to maximize properties such as adhesion or cleanability while minimizing the likelihood that the electrodes may become exposed. In some instances, two or more patterned electrodes may be placed at different depths within the dry adhesive material to optimize the performance of each electrode for its intended purpose. In some instances, a dry adhesive pad may comprise multiple layers of dry adhesive materials or other materials with patterned electrodes embedded at the interfaces between layers.

FIG. 4 depicts a schematic of an exemplary dry adhesive material 400 that contains two patterned electrodes arranged in an enveloping, rectangular fashion. The outer electrode comprises a first wire 401 that runs from terminal A to terminal A′. The inner electrode comprises a second wire 410 that runs from terminal B to terminal B′. The electrodes of FIG. 4 are patterned such that the first wire 401 is relatively thinner (e.g., in width) and always has a larger separation between counterdirectional segments as defined by the flow of an electrical current 430 than in the second wire 410. For example, in the pattern illustrated in FIG. 4, the separation gap between segments of the first wire 401 as defined by the segment Z1-Z2 will always exceed the separation gap between segments of the second wire 410 as defined by the segment Y1-Y2. The separation gaps of the respective wires may or may not be constant throughout the pattern in the dry adhesive material. In some examples (not shown in FIG. 4), the respective wires may trace a periphery of a shape of the dry adhesive material with decreasing radii. Alternatively, the separation gap of the first wire may be greater in some segments than the second wire, and less in other segments than the second wire. In other examples, multiple dry adhesive electrodes may be patterned in any other conceivable fashion, such as circular or triangular fashions.

The multiple electrodes may be contained within a single layer of dry adhesive material. Alternatively, the multiple electrodes may be contained within multiple layers of dry adhesive material, such that a first wire pattern in a first layer overlays a second wire pattern in a second layer. In some cases, a single wire may be contained within a single layer. In some cases, a single wire may traverse multiple layers.

The predetermined separation gap of an electrode comprising a conductive material patterned in a dry adhesive material may be varied for optimal performance. In some applications, an electrode pattern may be optimized to have a larger predetermined separation gap between segments of the electrode, while in other applications an electrode pattern may be optimized to have a smaller predetermined separation gap between segments of the electrode. The predetermined separation gap of an electrode in a dry adhesive material may be optimized for adhesion strength or cleanability of the dry adhesive material surface. In some examples, a patterned electrode configured for surface adhesion may be optimized to comprise a predetermined thinner conductive material (e.g., having relatively smaller minimum dimension) and a larger predetermined separation gap between segments of the electrode. In other examples, a patterned electrode configured for surface cleaning may be optimized to comprise a conductive material with a predetermined wider conductive material (e.g., having relatively larger minimum dimension) and a smaller predetermined separation gap between segments of the electrode. The same patterned electrode, configured for both surface adhesion and surface cleaning, may have an electrode pattern that is optimized for dual performance of such surface adhesion and surface cleaning. In some instances, the electrode pattern may be optimized based on a target contact surface or target contact material that the electroactuated dry adhesive material is configured to grip.

In some examples, the predetermined separation gap may be about 1 micron (μm), 10 μm, 25 μm, 50 μm, 100 μm, 200 μm, 300 μm, 400 μm, 500 μm, 750 μm, or about 1 millimeter (mm). In some examples, the predetermined separation gap may be at least about 1 μm, 10 μm, 25 μm, 50 μm, 100 μm, 200 μm, 300 μm, 400 μm, 500 μm, 750 μm, or at least about 1 mm. In some examples, the predetermined separation gap may be no more than about 1 mm, 750 μm, 500 μm, 400 μm, 300 μm, 200 μm, 100 μm, 50 μm, 25 μm, 10 μm, or no more than about 1 μm. In some examples, the predetermined separation gap may be in a range from about 1 μm to about 50 μm, about 1 μm to about 100 μm, about 1 μm to about 500 μm, about 1 μm to about 1 mm, about 50 μm to about 100 μm, about 50 μm to about 500 μm, about 50 μm to about 1 mm, about 100 μm to about 500 μm, about 100 μm to about 1 mm, or about 500 μm to about 1 mm.

The predetermined thickness (or predetermined width, interchangeably used herein) of a conductive material patterned as an electrode in a dry adhesive material may be varied for optimal performance. In some applications, an electrode may be optimized to have a thicker conductive material while in other applications, an electrode may be optimized to have a thinner conductive material. The predetermined thickness of an electrode in a dry adhesive material may be optimized to perform for adhesion strength or cleanability, or both, of the dry adhesive material surface. In some examples, the predetermined thickness of the conductive material may be about 10 μm, 25 μm, 50 μm, 100 μm, 200 μm, 300 μm, 400 μm, 500 μm, 750 μm, 1 mm or about 2 mm. In some examples, the predetermined thickness of the conductive material may be at least about 10 μm, 25 μm, 50 μm, 100 μm, 200 μm, 300 μm, 400 μm, 500 μm, 750 μm, 1 mm, or at least about 2 mm. In some examples, predetermined thickness of the conductive material may be no more than about 2 mm, 1 mm, 750 μm, 500 μm, 400 μm, 300 μm, 200 μm, 100 μm, 50 μm, 25 μm, or no more than about 10 μm. In some examples, the predetermined thickness of the conductive material may be in a range from about 10 μm to about 50 μm, about 10 μm to about 100 μm, about 10 μm to about 500 μm, about 10 μm to about 1 mm, about 10 μm to about 2 mm, about 50 μm to about 100 μm, about 50 μm to about 500 μm, about 50 μm to about 1 mm, about 50 μm to about 2 mm, about 100 μm to about 500 μm, about 100 μm to about 1 mm, about 100 μm to about 2 mm, about 500 μm to about 1 mm, about 500 μm to about 2 mm, or about 1 mm to about 2 mm.

Electrodes located within, near, or on a dry adhesive material may be embedded at a particular depth relative to the surface of the dry adhesive material. A dry adhesive material comprising two or more patterned electrodes may comprise electrodes located at different depths depending upon the optimal configuration for their intended function. In some examples, the depth of a patterned electrode may be about 1 μm, 10 μm, 25 μm, 50 μm, 100 μm, 200 μm, 300 μm, 400 μm, 500 μm, 750 μm, 1 mm or about 2 mm. In some examples, the depth of a patterned electrode may be at least about 1 μm, 10 μm, 25 μm, 50 μm, 100 μm, 200 μm, 300 μm, 400 μm, 500 μm, 750 μm, 1 mm, or at least about 2 mm. In some examples, the depth of a patterned electrode may be no more than about 2 mm, 1 mm, 750 μm, 500 μm, 400 μm, 300 μm, 200 μm, 100 μm, 50 μm, 25 μm, 10 μm or no more than about 1 μm. In some examples, the depth of a patterned electrode may be in a range from about 1 μm to about 50 μm, about 1 μm to about 100 μm, about 1 μm to about 500 μm, about 1 μm to about 1 mm, about 1 μm to about 2 mm, about 50 μm to about 100 μm, about 50 μm to about 500 μm, about 50 μm to about 1 mm, about 50 μm to about 2 mm, about 100 μm to about 500 μm, about 100 μm to about 1 mm, about 100 μm to about 2 mm, about 500 μm to about 1 mm, about 500 μm to about 2 mm, or about 1 mm to about 2 mm. A plurality of electrodes may be disposed at varying depths relative to the gripping surface of the dry adhesive material, for example, such that a first electrode may be disposed more proximal or distal to the gripping surface than a second electrode.

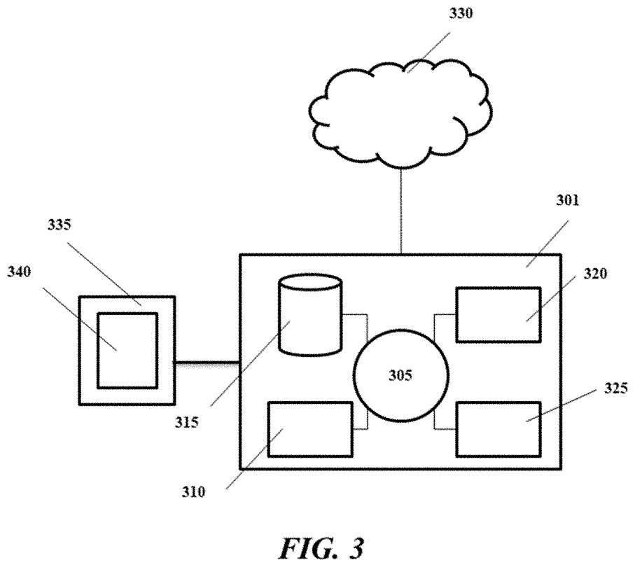

Electrodes located within, near, or on a dry adhesive material may be electrically connected or coupled to other electrical components that utilize the electrodes for their intended purpose, e.g., electrostatic actuation of the adhesive surface. Such electrical components may include one or more voltage-generating devices such as amplifiers, resistors, capacitors, wires, leads, grounds, batteries, switches, relays, and transformers. An electrode may be coupled or connected to one or more microprocessors (or processors) or components capable of transmitting a signal to a microprocessor or processor, e.g., a wireless router. The function of an electrode or a system containing an electrode may be controlled by a computational system comprising a microprocessor. A computational algorithm may be used, for instance, to control the cycling of an electrostatic cleaning process for a system comprising an electroactuated dry adhesive material. Example computational systems are described with respect to FIG. 3 for example. One or more microprocessors (or processors) as described elsewhere herein may be configured to optimize and determine a width and/or separation gap of or between one or more electrodes based on one or more applications (e.g., cleaning, adhesion, adhesion for stacking, both cleaning and adhesion, etc.).

A dry adhesive material may comprise a component of a larger device or component. A dry adhesive material may be a component of a larger device or component. In some instances, the dry adhesive material may be utilized for a system such as a robotic gripping system or a tactile sensing system. In some instances, a system comprising a dry adhesive material may comprise other elements of utility, such as, but not limited to, thermal elements, magnetic elements, electromagnetic elements, ultrasonic elements or rotational elements.

Adhesion between a dry adhesive material and another material may be characterized by the stress required to break the interface between the two materials. In some instances, the adhesion strength between a dry adhesive material and another material may be characterized by a separation shear strength. A separation shear strength may be characterized by the load necessary to break the interface between two materials when the load is applied parallel to the interface. In other instances, the adhesion strength between a dry adhesive material and another material may be characterized by a normal strength. A normal strength may be characterized by the tension load necessary to break the interface between two materials when the load is applied in an orthogonal direction to the interface. The strength of adhesion may also be characterized by other methods, such as combined normal and shear stresses, e.g., via rotational loading around an axis parallel to the interface. A voltage-generating system may comprise one or more such voltage-generating devices.

A normal stress strength may be measured to characterize the strength of adhesion of a dry adhesive material. The normal stress may be a function of the properties of the dry adhesive material and the properties of the material to which the adhesive is adhered. For example, a dry adhesive material may have a lower normal stress strength when adhered to a rough or non-planar surface than when adhered to a smoother or more planar surface. The normal stress strength of a dry adhesive material may be measured by mechanical testing. In some cases, the normal stress strength of the dry adhesive material adhered with another material may be about 0.01 kiloPascals (kPa), 0.1 kPa, 0.2 kPa, 0.3 kPa, 0.4 kPa, 0.5 kPa, 0.6 kPa, 0.7 kPa, 0.8 kPa, 0.9 kPa, 1 kPa, 2 kPa, 3 kPa, 4 kPa, 5 kPa, 6 kPa, 7 kPa, 8 kPa, 9 kPa, 10 kPa, 11 kPa, 12 kPa, 13 kPa, 14 kPa, 15 kPa, 16 kPa, 17 kPa, 18 kPa, 19 kPa, 20 kPa, 30 kPa, 40 kPa, or about 50 kPa. In some cases, the normal stress strength of the dry adhesive material adhered with another material may be at least about 0.01 kPa, 0.1 kPa, 0.2 kPa, 0.3 kPa, 0.4 kPa, 0.5 kPa, 0.6 kPa, 0.7 kPa, 0.8 kPa, 0.9 kPa, 1 kPa, 2 kPa, 3 kPa, 4 kPa, 5 kPa, 6 kPa, 7 kPa, 8 kPa, 9 kPa, 10 kPa, 11 kPa, 12 kPa, 13 kPa, 14 kPa, 15 kPa, 16 kPa, 17 kPa, 18 kPa, 19 kPa, 20 kPa, 30 kPa, 40 kPa, or at least about 50 kPa or more. In some cases, the normal stress strength of the dry adhesive material adhered with another material may be no more than about 50 kPa, 40 kPa, 30 kPa, 20 kPa, 19 kPa, 18 kPa, 17 kPa, 16 kPa, 15 kPa, 14 kPa, 13 kPa, 12 kPa, 11 kPa, 10 kPa, 9 kPa, 8 kPa, 7 kPa, 6 kPa, 5 kPa, 4 kPa, 3 kPa, 2 kPa, 1 kPa, 0.9 kPa, 0.8 kPa, 07 kPa, 0.6 kPa, 0.5 kPa, 0.4 kPa, 0.3 kPa, 0.2 kPa, 0.1 kPa, or no more than about 0.01 kPa or less.

The magnitude of a dry adhesive material's normal stress strength may be altered by physical or chemical changes to the material. In some instances, accumulation of particulate matters, fouling by chemicals, physical damage, chemical degradation, or other changes to the dry adhesive material may alter (e.g., reduce) the ability of the dry adhesive to adhere to other materials. In other instances, electroactuation of the dry adhesive surface by an electric field may increase the normal stress strength of the dry adhesive material. The change in the normal stress strength of a dry adhesive material due to physical or chemical alteration may be expressed as a percentage change in the normal stress between the altered material and the pristine material. In some instances, the altered dry adhesive material normal stress strength may be about 5%, 10%, 20%, 30%, 40%, 50%, 60%, 70%, 80%, 90%, 100%, 110%, 120%, 150%, or about 200% of the pristine normal stress strength. In some instances, the altered dry adhesive material normal stress strength may be at least about 5%, 10%, 20%, 30%, 40%, 50%, 60%, 70%, 80%, 90%, 100%, 110%, 120%, 150%, or at least about 200% or more of the pristine normal stress strength. In some instances, the altered dry adhesive material normal stress strength may be no more than about 200%, 150%, 120%, 110%, 100%, 90%, 80%, 70%, 60%, 50%, 40%, 30%, 20%, 10%, or no more than about 5% or less of the pristine normal stress strength.

The magnitude of a dry adhesive material's separation shear stress strength may be altered by physical or chemical changes to the material. In some instances, accumulation of particulate matters, fouling by chemicals, physical damage, chemical degradation, or other changes to the dry adhesive material may alter (e.g., reduce) the ability of the dry adhesive to adhere to other materials. In other instances, electroactuation of the dry adhesive surface by an electric field may increase the separation shear stress strength of the dry adhesive material. The change in the separation shear stress strength of a dry adhesive material due to physical or chemical alteration may be expressed as a percentage change in the shear stress between the altered material and the pristine material. In some instances, the altered dry adhesive material separation shear stress strength may be about 5%, 10%, 20%, 30%, 40%, 50%, 60%, 70%, 80%, 90%, 100%, 110%, 120%, 150%, or about 200% of the pristine separation shear stress strength. In some instances, the altered dry adhesive material separation shear stress strength may be at least about 5%, 10%, 20%, 30%, 40%, 50%, 60%, 70%, 80%, 90%, 100%, 110%, 120%, 150%, or at least about 200% or more of the pristine separation shear stress strength. In some instances, the altered dry adhesive material separation shear stress strength may be no more than about 200%, 150%, 120%, 110%, 100%, 90%, 80%, 70%, 60%, 50%, 40%, 30%, 20%, 10%, or no more than about 5% or less of the pristine separation shear stress strength.

A separation shear stress strength may be measured to characterize the strength of adhesion of a dry adhesive material. The separation shear stress may be a function of the properties of the dry adhesive material and the properties of the material to which the adhesive is adhered. For example, a dry adhesive material may have a lower separation shear stress strength when adhered to a rough or non-planar surface than when adhered to a smoother or more planar surface. The separation shear stress strength of a dry adhesive material may be measured by mechanical testing. The separation shear stress strength of a dry adhesive material adhered with another material may be about 1 kPa, 5 kPa, 10 kPa, 15 kPa, 20 kPa, 25 kPa, 30 kPa, 35 kPa, 40 kPa, 45 kPa, 50 kPa, 55 kPa, 60 kPa, 65 kPa, 70 kPa, 80 kPa, 85 kPa, 90 kPa, 100 kPa, 150 kPa, or about 200 kPa. The separation shear stress strength of a dry adhesive material adhered with another material may be at least about 1 kPa, 5 kPa, 10 kPa, 15 kPa, 20 kPa, 25 kPa, 30 kPa, 35 kPa, 40 kPa, 45 kPa, 50 kPa, 55 kPa, 60 kPa, 65 kPa, 70 kPa, 80 kPa, 85 kPa, 90 kPa, 100 kPa, 150 kPa, or at least about 200 kPa or more. The separation shear stress strength of a dry adhesive material adhered with another material may be no more than about 200 kPa, 150 kPa, 100 kPa, 90 kPa, 85 kPa, 80 kPa, 75 kPa, 70 kPa, 65 kPa, 60 kPa, 55 kPa, 50 kPa, 45 kPa, 40 kPa, 35 kPa, 30 kPa, 25 kPa, 15 kPa, 10 kPa, 5 kPa, or no more than about 1 kPa or less.

The adhesion strength of dry adhesive material systems may be altered (e.g., reduced) when exposed to sources of particulate matter and other forms of contamination. Without wishing to be bound by theory, particulate matter may affect the performance of dry adhesive materials by several mechanisms including reducing the ability of microstructures to contact an opposing surface, and reducing the van der Waals interactions between the dry adhesive and an opposing surface. Contaminants may include particulate matter such as dust, soot, and lint. Dry adhesive materials may also be affected by the deposition of airborne matter or aerosols, including liquid and solid particles. Dust particulate matter may include, but is not limited to, mineral matter, magnetic materials, radioactive materials, biological materials (e.g. dead skin cells), ceramic particles, metal particles, and dirt. Particulates may arise in any operating environment where dry adhesive systems are used. Particulates may include airborne particles as well as particles on a surface. In some instances, particulate matter may be left on a surface as a residual product of a manufacturing process. Particulate matter and other contaminants may have physical or chemical characteristics, e.g. magnetic fields or electrical charge, that affect its ability to bind to a dry adhesive material.

Particulate matter, including dust particles, may be characterized by an average particle size. Particulate matter described in the present disclosure may be at least about 1 micron (μm), 5 μm, 10 μm, 20 μm, 30 μm, 40 μm, 50 μm, 60 μm, 70 μm, 80 μm, 90 μm, 100 μm, 120 μm, 140 μm, 160 μm, 180 μm, 200 μm, or at least about 500 μm or more. Particulate matter may be no more than about 500 μm, 200 μm, 180 μm, 160 μm, 140 μm, 120 μm, 100 μm, 90 μm, 80 μm, 70 μm, 60 μm, 50 μm, 40 μm, 30 μm, 20 μm, 10 μm, 5 μm, or no more than about 1 μm. Particulate matter may be in a range from about 1 μm to about 5 μm, about 1 μm to about 10 μm, about 1 μm to about 20 μm, about 1 μm to about 50 μm, about 1 μm to about 100 μm, about 1 μm to about 200 μm, about 1 μm to about 500 μm, about 5 μm to about 10 μm, about 5 μm to about 20 μm, about 5 μm to about 50 μm, about 5 μm to about 100 μm, about 1 μm to about 200 μm, about 5 μm to about 500 μm, about 10 μm to about 20 μm, about 10 μm to about 50 μm, about 10 μm to about 100 μm, about 10 μm to about 200 μm, about 10 μm to about 500 μm, about 20 μm to about 50 μm, about 20 μm to about 100 μm, about 20 μm to about 200 μm, about 20 μm to about 500 μm, about 50 μm to about 100 μm, about 50 μm to about 200 μm, about 50 μm to about 500 μm, about 100 μm to about 200 μm, about 100 μm to about 500 μm, or about 200 μm to about 500 μm. Particulate sizes may be characterized by a distribution. Particulate size distributions may be monodisperse, polydisperse, or random.

The quantity of particulate matter or other contaminants adhering to a dry adhesive material may be quantified in various ways. In some instances, particulate matter may be quantified by a measurement or estimate of total particles adhered to the dry adhesive surface. A dry adhesive material may have at least about 1, 10, 100, 1,000, 10,000, 100,000, or at least about 1,000,000 particles or more adhered to its surface or a region of its surface. A dry adhesive material may have no more than about 1,000,000, 100,000, 10,000, 1,000, 100, 10, or no more than about 1 particle or less adhered to its surface or a region of its surface. In other instances, particulate matter may be quantified by a measurement or estimate of total surface area coverage of particles adhered to the dry adhesive surface. A dry adhesive material may have at least about 0.01%, 0.1%, 1%, 5%, 10%, 20%, 50%, 90%, or at least about 99% or more of its surface area covered in adhered particulate matter. A dry adhesive material may have no more than about 99%, 90%, 50%, 20%, 10%, 5%, 1%, 0.1%, or no more than about 0.01% or less of its surface area covered in adhered particulate matter. The distribution of particles or other contaminants on the surface of a dry adhesive material may be uniform or non-homogeneous.

Particulate matter or other contaminants may deposit, aggregate, or adhere to the surface of a dry adhesive. The accumulation of particulate matter or other contaminants on a dry adhesive surface may result in a partial or total loss of adhesion strength. The deposition of particulate matter may have differing effects on adhesion strength depending upon the average size of the particles. For example, a particle that is smaller than the size of a microstructure on a dry adhesive surface may not cause full adhesion loss because some or all of the microstructure may still be capable of contacting an opposing surface. By contrast, a particle that is larger than the size of a microstructure on a dry adhesive surface may cause full adhesion loss as most or all of the microstructure may be blocked from contacting an opposing surface. A dry adhesive material may experience an adhesion strength loss of about 1%, 5%, 10%, 20%, 30%, 40%, 50%, 60%, 70%, 80%, 90% or about 100%. A dry adhesive material may experience an adhesion strength loss of at least about 1%, 5%, 10%, 20%, 30%, 40%, 50%, 60%, 70%, 80%, 90% or at least about 99% or more. A dry adhesive material may experience an adhesion strength loss of no more than about 99%, 90%, 80%, 70%, 60%, 50%, 40%, 30%, 20%, 10%, 5%, or no more than about 1% or less.

The removal or separation of particulate matter from a dry adhesive material may result in the recovery of some or all of the material's adhesion strength. In some instances, damage to the dry adhesive (e.g. removal of microstructures) may result in the permanent loss of adhesion strength relative to a pristine dry adhesive. In other instances, the removal of non-damaging or non-reactive contaminants (e.g. dust) may result in a partial or complete restoration of adhesion strength. In some instances, adhesion strength recovery may be characterized by the absolute measure of a normal stress strength or a shear stress strength for the dry adhesive material. In other instances, adhesion strength recovery may be characterized by a recovery of a normal stress strength or a shear stress strength relative to a pristine dry adhesive material. A cleaned dry adhesive material may experience an adhesion strength recovery of about 1%, 5%, 10%, 20%, 30%, 40%, 50%, 60%, 70%, 80%, 90% or about 100%. A cleaned dry adhesive material may experience an adhesion strength recovery of at least about 1%, 5%, 10%, 20%, 30%, 40%, 50%, 60%, 70%, 80%, 90% or at least about 99% or more. A cleaned dry adhesive material may experience an adhesion strength recovery of no more than about 99%, 90%, 80%, 70%, 60%, 50%, 40%, 30%, 20%, 10%, 5%, or no more than about 1% or less.

In some instances, a dry adhesive material may be cleaned to remove particulate matter or other contaminants. Cleaning may occur during the operation of a device that utilizes the dry adhesive material (e.g., during adhesion to a target surface). In some instances, cleaning may be a continuous or semi-continuous process that actively prevents, reduces, minimizes, or mitigates the accumulation of particulate matter or other contaminants on a dry adhesive material. Cleaning may occur as a process that is separate from the operation of a device that utilizes the dry adhesive material. Cleaning may involve a single cleaning process or more than one process. Cleaning processes may occur sequentially or in parallel. Multiple cleaning processes may occur simultaneously or substantially simultaneously. One or more cleaning processes may run once or utilize more than one cycle to remove particulate matter or other contaminants from a dry adhesive material. In some instances, a cleaning process may have about 1, 2, 3, 4, 5, 6, 7, 8, 9, 10, 11, 12, 13, 14, 15, 16, 17, 18, 19, 20, 21, 22, 23, 24, 25, 26, 27, 28, 29, or about 30 cycles or more. A cleaning process may have at least about 1, 2, 3, 4, 5, 6, 7, 8, 9, 10, 11, 12, 13, 14, 15, 16, 17, 18, 19, 20, 21, 22, 23, 24, 25, 26, 27, 28, 29, or at least about 30 cycles or more. A cleaning process may have no more than about 30, 29, 28, 27, 26, 25, 24, 23, 22, 21, 20, 19, 18, 17, 16, 15, 14, 13, 12, 11, 10, 9, 8, 7, 6, 5, 4, 3, 2, or no more than about 1 cycle.

A cleaning process may be run for a sufficient number of cycles to meet a targeted cleaning efficacy as determined by an objective measure such as adhesion strength recovery. A cleaning efficacy may be defined as the percentage recovery of one or more dry adhesive properties (e.g., adhesion strength) after a cleaning process has occurred. In some instances, a cleaning efficacy may be measured after a single cleaning cycle. In other instances, a cleaning efficacy may be measured after more than one cleaning cycle. For example, a multi-electrode dry adhesive material may have a starting shear adhesion strength of 100 kPa when clean. If particulate contamination reduces the shear adhesion strength to 50 kPa and subsequent cleaning restores the shear adhesion strength to 75 kPa, the cleaning efficacy may be calculated to be 50% due to the recovery of half of the lost shear strength.

The cleaning of a multi-electrode dry adhesive material may have a cleaning efficacy of about 5%, 10%, 20%, 30%, 40%, 50%, 60%, 70%, 80%, 90%, 95% or about 99%. The cleaning of a multi-electrode dry adhesive material may have a cleaning efficacy of at least about 5%, 10%, 20%, 30%, 40%, 50%, 60%, 70%, 80%, 90%, 95% or at least about 99%. The cleaning of a multi-electrode dry adhesive material may have a cleaning efficacy of no more than about 99%, 95%, 90%, 80%, 70%, 60%, 50%, 40%, 30%, 20%, 10%, or 5% or less. In some instances, the cleaning efficacy of a dry adhesive material may vary due to the chemical and physical nature of any contaminant materials. For example, the particle size distribution or electrostatic character of a particular contaminant may alter the number of cycles necessary to achieve a targeted cleaning efficacy.

A cleaning method or cleaning cycle for a dry adhesive material may have a particular duration. The duration of a cleaning method or cleaning cycles may be about 1 second (s), 5 s, 10 s, 20 s, 30 s, 1 minute (min), 5 min, 10 min, 20 min, 30 min, 1 hour (hr), 2 hrs or more. The duration of a cleaning method or cleaning cycles may be at least about 1 second (s), 5 s, 10 s, 20 s, 30 s, 1 minute (min), 5 min, 10 min, 20 min, 30 min, 1 hour (hr), or at least about 2 hrs or more. The duration of a cleaning cycle may be no more than about 2 hrs, 1 hr, 30 min, 20 min, 10 min, 5 min, 1 min, 30 s, 20 s, 10 s, 5 s, or no more than about is or less.

A cleaning method or cleaning cycle may operate regularly, intermittently, randomly, or at timed intervals. A cleaning method or cleaning cycle may occur during particular modes of operation, e.g., when the electroactuated adhesive is not gripping a surface. A cleaning method or cleaning cycle may not occur during particular modes of operation, e.g., when the electroactuated adhesive is in contact with a surface. A cleaning method or cleaning cycle may have a particular duty cycle. A duty cycle may be defined as the percentage of time during a set period in which the cleaning electrode is activated. A cleaning method or cleaning cycle may have a duty cycle of about 5%, 10%, 15%, 20%, 25%, 30%, 35%, 40%, 45%, 50%, 55%, 60%, 65%, 70%, 75%, 80%, 85%, 90%, 95%, or 99%. A cleaning method or cleaning cycle may have a duty cycle of at least about 5%, 10%, 15%, 20%, 25%, 30%, 35%, 40%, 45%, 50%, 55%, 60%, 65%, 70%, 75%, 80%, 85%, 90%, 95%, or 99% or more. A cleaning method or cleaning cycle may have a duty cycle of no more than about 99%, 95%, 90%, 85%, 80%, 75%, 70%, 65%, 60%, 55%, 50%, 45%, 40%, 35%, 30%, 25%, 20%, 15%, 10%, or 5% or less.

In some instances, a cleaning process to remove particulate matter or other contaminants from a dry adhesive material may be a non-contact method, or a wet contact method.

A non-contact cleaning method for a dry adhesive material may comprise electrostatic repulsion. A wet contact cleaning method may include, but is not limited to, water or isopropyl alcohol cleaning.

Electrostatic cleaning may be utilized to separate particulate matter or other contaminants from the surface of a dry adhesive material. Electrodes or other electrical elements may be embedded within a dry adhesive material or contained within a device or component that comprises a dry adhesive material. The electrodes may be utilized to generate a static or variable electric field at or near the surface of the dry adhesive material. An electrostatic cleaning method may be operated utilizing alternating current electrical field with one, two, three or more phases. The phases may have a phase differential of about 1 hertz (Hz), 5 Hz, 10 Hz, 20 Hz or more. An electrostatic cleaning method may utilize a voltage differential of about 100 volts (V), 500 V, 1 kilovolt (kV), 2 kV, 3 kV, 4 kV, 5 kV, 10 kV or more. An electrostatic cleaning method may utilize a voltage differential of at least about 100 V, 500 V, 1 kV, 2 kV, 3 kV, 4 kV, 5 kV, or at least about 10 kV or more. An electrostatic cleaning method may utilize a voltage differential of no more than about 10 kV, 5 kV, 4 kV, 3 kV, 2 kV, 1 kV, 500 V, no more than about 100 V or less. The electrostatic element may oscillate between a high and low voltage in a sinusoidal or square wave pattern. The electrostatic element may oscillate between a high and low voltage in a standing or traveling wave. The peak-to-peak voltage may have a period of about 1 s, 10 s, 30 s, 1 min, 5 min, or more.

Solvent cleaning may be utilized to separate particulate matter or other contaminants from the surface of a dry adhesive material. Any appropriate non-reactive solvent may be utilized to clean a dry adhesive material including, but not limited to, water, methanol, ethanol, isopropyl alcohol, acetone, methyl ethyl ketone, dimethyl ether, methyl acetate, and hexanes. One or more solvents may be used in a solvent cleaning process. Solvent cleaning may involve immersion of the dry adhesive material in the solvent or application of the solvent to the dry adhesive material. In some instances, further agitation of the dry adhesive material may occur in the presence of a solvent, such as bath sonication or frictional contact of the adhesive surface with another material (e.g. a soft sponge). Solvent cleaning may further involve additional steps such as rinsing and drying the dry adhesive material. Rinsing may utilize the same solvent or a different solvent. Drying may occur via heating, vacuum, or gas purging.

A cleaning method for a dry adhesive material may involve more than one cleaning process. For example, the cleaning method may comprise electrostatic cleaning and wet cleaning (e.g., in succession). A system or device comprising a dry adhesive material may comprise a pressurized air source that displaces particulate matter or other contaminants from the material surface. Cleaning processes such as electrostatic cleaning may be combined with air displacement to increase the efficiency of cleaning processes. A system or device comprising a dry adhesive material may comprise a vacuum source that displaces particulate matter or other contaminants from the material surface. Cleaning processes such as electrostatic cleaning may be combined with vacuum displacement to increase the efficiency of cleaning processes.

Methods may also be employed to actively prevent, reduce, minimize, or mitigate the accumulation of particulate matter or other contaminants during the utilization of a system comprising a dry adhesive material. For example, electrostatic repulsion or magnetic repulsion may be utilized when a dry adhesive material system is not adhered or in contact with another surface to prevent or reduce the deposition of airborne particulates. Methods such as gas purging of a surface may occur before contact with a dry adhesive material to sweep particulate matter from the surface.

A device comprising a dry adhesive material with multiple patterned electrodes may be used for any appropriate application. In some instances, a dry adhesive material with multiple patterned electrodes may be used for adhering to materials with curved, warped, non-uniform or complex surfaces, such as structural materials (e.g., pipes or metal beams). In some instances, a dry adhesive material with multiple patterned electrodes may be used for adhering to materials with smooth or non-textured surfaces, for example glass or polished metal. In some instances, a dry adhesive material with multiple patterned electrodes may be used for tasks such as sorting and separation for materials, e.g., separating fabric sheets or prepreg carbon fiber sheets. A device comprising a dry adhesive material with multiple patterned electrodes may be used in any suitable environment, including environments where dust or particulate contamination may be mitigated by the electroactuation of one or more of the patterned electrodes. Exemplary environments may include industrial settings or external environments.

While systems, devices, and methods utilizing multi-electrode approaches have been described with respect to electroactuated dry adhesives, it will be appreciated that the approaches is applicable to electroactuated adhesives with any surfaces compatible with electrostatic adhesion.

### Computer Control Systems

The present disclosure provides computer control systems that are programmed to implement methods of the disclosure. FIG. 3 shows a computer control system 301 that is programmed or otherwise configured to produce an electrical potential in an electroactuated adhesion device. The computer control system 301 can regulate various aspects of the methods of the present disclosure, such as, for example, computing and generating the electrostatic potential for the purposes of adhesion and/or cleaning of an electroactuated adhesion device, tactile sensing (e.g., inferred from an impedance measurement), and the like. The computer control system 301 can be implemented on an electronic device of a user or a computer system that is remotely located with respect to the electronic device. The electronic device can be a mobile electronic device.

The computer system 301 includes a central processing unit (CPU, also “processor” and “computer processor” herein) 305, which can be a single core or multi core processor, or a plurality of processors for parallel processing. One or more processors (or microprocessors) may, individually or in combination, perform and regulate various aspects of the systems and methods of the present disclosure. The computer control system 301 also includes memory or memory location 310 (e.g., random-access memory, read-only memory, flash memory), electronic storage unit 315 (e.g., hard disk), communication interface 320 (e.g., network adapter) for communicating with one or more other systems, and peripheral devices 325, such as cache, other memory, data storage and/or electronic display adapters. The memory 310, storage unit 315, interface 320 and peripheral devices 325 are in communication with the CPU 305 through a communication bus (solid lines), such as a motherboard. The storage unit 315 can be a data storage unit (or data repository) for storing data. The computer control system 301 can be operatively coupled to a computer network (“network”) 330 with the aid of the communication interface 320. The network 330 can be the Internet, an internet and/or extranet, or an intranet and/or extranet that is in communication with the Internet. The network 330 in some cases is a telecommunication and/or data network. The network 330 can include one or more computer servers, which can enable distributed computing, such as cloud computing. The network 330, in some cases with the aid of the computer system 301, can implement a peer-to-peer network, which may enable devices coupled to the computer system 301 to behave as a client or a server.

The CPU 305 can execute a sequence of machine-readable instructions, which can be embodied in a program or software. The instructions may be stored in a memory location, such as the memory 310. The instructions can be directed to the CPU 305, which can subsequently program or otherwise configure the CPU 305 to implement methods of the present disclosure. Examples of operations performed by the CPU 305 can include fetch, decode, execute, and writeback.

The CPU 305 can be part of a circuit, such as an integrated circuit. One or more other components of the system 301 can be included in the circuit. In some cases, the circuit is an application specific integrated circuit (ASIC).

The storage unit 315 can store files, such as drivers, libraries and saved programs. The storage unit 315 can store user data, e.g., user preferences and user programs. The computer system 301 in some cases can include one or more additional data storage units that are external to the computer system 301, such as located on a remote server that is in communication with the computer system 301 through an intranet or the Internet.

The computer system 301 can communicate with one or more remote computer systems through the network 330. For instance, the computer system 301 can communicate with a remote computer system of a user (e.g., a user controlling the operation of an electroactuated adhesion device). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 301 via the network 330.

Methods as described herein can be implemented by way of machine (e.g., computer processor) executable code stored on an electronic storage location of the computer system 301, such as, for example, on the memory 310 or electronic storage unit 315. The machine executable or machine readable code can be provided in the form of software. During use, the code can be executed by the processor 305. In some cases, the code can be retrieved from the storage unit 315 and stored on the memory 310 for ready access by the processor 305. In some situations, the electronic storage unit 315 can be precluded, and machine-executable instructions are stored on memory 310.

The code can be pre-compiled and configured for use with a machine having a processer adapted to execute the code, or can be compiled during runtime. The code can be supplied in a programming language that can be selected to enable the code to execute in a pre-compiled or as-compiled fashion.

Aspects of the systems and methods provided herein, such as the computer system 301, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 301 can include or be in communication with an electronic display 335 that comprises a user interface (UI) 340 for providing, for example, parameters for controlling the electric potential in an electrode of an electroactuated adhesion device. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 305. The algorithm can, for example, regulate the electric potential of one or more electrodes in an electroactuated adhesion device to optimize the adhesion strength of the device. As another example, the algorithm can regulate the electric potential of one or more electrodes in an electroactuated adhesion device to optimize the surface cleaning of the electroactuated adhesion device.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. An electroactuated adhesion system, comprising:
a substrate comprising a surface, wherein the surface comprises a plurality of microstructures, wherein the plurality of microstructures are configured to interface a target surface;
two or more patterned electrodes embedded therein or coupled to the substrate, wherein each patterned electrode (i) comprises a conductive material of a respective predetermined thickness, and (ii) is patterned in the substrate to have a respective predetermined minimum separation gap between substantially parallel segments of the each patterned electrode; and
one or more voltage-generating systems in electrical connectivity with the two or more patterned electrodes, wherein the one or more voltage-generating systems are configured to activate the two or more patterned electrodes, individually or simultaneously.

2. The electroactuated adhesion system of claim 1, wherein one or both of the predetermined minimum separation gap and the predetermined thickness is determined based at least in part on the type of target surface.

3. The electroactuated adhesion system of claim 1, wherein the substrate comprises an elastomer.

4. The electroactuated adhesion system of claim 1, wherein the conductive material comprises one or more materials selected from the group consisting of: copper, silver, graphite, brass, titanium, platinum, palladium, and mixed metal oxides.

5. The electroactuated adhesion system of claim 1, wherein the electrode comprises one or more materials selected from the group consisting of: copper, silver, graphite, brass, titanium, platinum, palladium, and mixed metal oxides.

6. The electroactuated adhesion system of claim 1, wherein the predetermined thickness of the conductive material is at least about 50 microns.

7. The electroactuated adhesion system of claim 1, wherein the predetermined thickness of the conductive material is no more than about 500 microns.

8. The electroactuated adhesion system of claim 1, wherein the predetermined separation gap of a given patterned electrode is at least about 100 microns.

9. The electroactuated adhesion system of claim 1, wherein the predetermined separation gap of the given patterned electrode is no more than about 1 millimeter.

10. The electroactuated adhesion system of claim 1, wherein a first predetermined separation gap of a first patterned electrode of the two or more patterned electrodes differs from a second predetermined separation gap of a second patterned electrode of the two or more patterned electrodes.

11. The electroactuated adhesion system of claim 1, wherein a first patterned electrode of the two or more patterned electrodes comprises a larger thickness of the conductive material and a smaller separation gap, and a second patterned electrode of the two or more patterned electrodes comprises a smaller thickness of the conductive material and a larger separation gap.

12. The electroactuated adhesion system of claim 11, wherein the first patterned electrode is configured to facilitate adhesion to the target surface, and wherein the one or more voltage-generating systems are configured to activate the first patterned electrode to adhere to the target surface.

13. The electroactuated adhesion system of claim 11, wherein the second patterned electrode is configured to facilitate cleaning of a surface of the dry adhesive material, and wherein the one or more voltage-generating systems are configured to activate the first patterned electrode to (i) clean the surface or (ii) prevent particulate accumulation on the surface.

14. The electroactuated adhesion system of claim 1, further comprising a microprocessor system.

15. The electroactuated adhesion system of claim 14, wherein the microprocessor system is configured to control the one or more voltage-generating systems.

16. The electroactuated adhesion system of claim 14, wherein the microprocessor system is configured to (i) receive a capacitance measurement from the two or more patterned electrodes, and (ii) determine one or more contact properties with the target surface.

17. The electroactuated adhesion system of claim 1, wherein the microprocessor system is configured to transmit a voltage input instruction to the one or more voltage-generating systems.

18. The electroactuated adhesion system of claim 17, wherein the voltage input instruction is based at least in part on a type of the target surface.

19. The electroactuated adhesion system of claim 1, wherein the substrate is configured to adhere to a plurality of adjacent materials comprising the target surface.

20. The electroactuated adhesion system of claim 1, wherein the two or more patterned electrodes are embedded in a single layer of the substrate.

21. (canceled)

22. (canceled)

23. (canceled)
